(19) United States
(12) Patent Application Publication
(10) Pub. No.: US 2009/0261867 A1
(43) Pub. Date: Oct. 22, 2009

(54) SEMICONDUCTOR DEVICE HAVING VOLTAGE OUTPUT CIRCUIT

(75) Inventors: Kumio Gundo, Kanagawa-ken (JP); Hidehiko Tachibana, Oita-ken (JP); Kouji Nakashima, Oita-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/424,892

(22) Filed: Apr. 16, 2009

(30) Foreign Application Priority Data
Apr. 18, 2008 (JP) 2008-109462

(51) Int. Cl. H03K 3/00

(52) U.S. Cl. 327/108

(57) ABSTRACT

Input and output nodes, an output circuit and a drive circuit are provided. The output circuit includes first and second n-channel MOS transistors connected to each other in series. A drain of the first n-channel MOS transistor is connected to a first line. A source of the first n-channel MOS transistor, a drain of the second n-channel MOS transistor, and a drain of a first p-channel MOS transistor are commonly connected to the output node. A source of the second n-channel MOS transistor is connected to a second line. A source of the first p-channel MOS transistor is connected to the first line. The drive circuit generates first to third control signals in response to an input signal provided to the input node. The control signals are respectively outputted to gates of the first and second n-channel MOS transistors and to a gate of the first p-channel MOS transistor.

### CROSS REFERENCE TO RELATED APPLICATION

This application is based upon and claims the benefit of priority from the prior Japanese Patent Application No. 2008-109462, filed on Apr. 18, 2008, the entire contents of which are incorporated herein by reference.

### FIELD OF THE INVENTION

The invention relates to a semiconductor device having a voltage output circuit.

### DESCRIPTION OF THE RELATED ART

A CMOS inverter is used for a voltage output circuit which is provided in a liquid crystal driver. The CMOS inverter is generally composed of a p-channel MOS transistor and an n-channel MOS transistor which have high breakdown voltage respectively.

A p-channel MOS transistor has lower current drivability than an n-channel MOS transistor. Accordingly, the p-channel MOS transistor needs to be larger in size than the n-channel MOS transistor in order to acquire a desired current value. For this reason, it is difficult to reduce the chip size of a semiconductor device having such a CMOS inverter as a high voltage output circuit.

Japanese Patent Application Publication No. 2000-77534 discloses an inverter circuit composed of n-channel MOS transistors having high current drivability.

The inverter circuit is provided with first and second n-channel MOS transistors, and a switching circuit. The first and second n-channel MOS transistors are respectively formed in p-type wells. Each of the p-type wells is formed in each of n-type wells which are formed separately from each other in a p-type semiconductor substrate. Thus, each of the first and second n-channel MOS transistors has a “Triple Well Structure”.

A source of the first n-channel MOS transistor and the semiconductor substrate are connected in common to each other. A drain of the first n-channel MOS transistor is connected to a first voltage source. A first switching control signal is applied to a gate of the first n-channel MOS transistor.

A drain of the second n-channel MOS transistor is connected to the source of the first n-channel MOS transistor. A source of the second n-channel MOS transistor and the semiconductor substrate are connected to a second voltage source. A second switching control signal is applied to a gate of the second n-channel MOS transistor.

The switching circuit provides the first or second switching control signal to perform control such that voltage from the first or second voltage source can be selectively applied to an output side.

An inverter circuit having such a structure is less likely to be affected by the back-gate bias effect of the first and second n-channel MOS transistors. Therefore, even when a source voltage being supplied for the first and second switching control signals is small, a desired output voltage can be supplied to an output node by switching the first and second n-channel MOS transistors using the switching circuit.

However, the inverter circuit may cause the problem that the output of the inverter circuit is affected by a threshold voltage of the first n-channel MOS transistor so that the output voltage of the inverter circuit decreases.

### SUMMARY OF THE INVENTION

An aspect of the present invention provides a semiconductor device, which includes an input node, a drive circuit, a first p-channel insulated-gate field-effect transistor, an output circuit and an output node, wherein the output circuit includes first and second n-channel insulated-gate field-effect transistors connected to each other in series, a drain of the first n-channel insulated-gate field-effect transistor is connected to a first line, a source of the first n-channel insulated-gate field-effect transistor is connected to the output node, a back gate of the first n-channel insulated-gate field-effect transistor is connected to the source, a drain of the second n-channel insulated-gate field-effect transistor is connected to the output node, a source of the second n-channel insulated-gate field-effect transistor is connected to a second line, a back gate of the second n-channel insulated-gate field-effect transistor is connected to the source of the second n-channel insulated-gate field-effect transistor, a source of the first p-channel insulated-gate field-effect transistor is connected to the first line, a drain of the first p-channel insulated-gate field-effect transistor is connected to the output node, and a back gate of the first p-channel insulated-gate field-effect transistor is connected to the source of the first p-channel insulated-gate field-effect transistor, and wherein the drive circuit generates first and second control signals to turn on and off the first and second n-channel insulated-gate field-effect transistors in a complementary manner, and generates a third control signal to control the first p-channel insulated-gate field-effect transistor, in response to an input signal provided to the input node, the first, the second and the third control signals being respectively outputted to gates of the first and the second n-channel insulated-gate field-effect transistors and to a gate of the first p-channel insulated-gate field-effect transistor.

Another aspect of the present invention provides a semiconductor device, which includes an input node, a plurality of voltage output circuits each including an output circuit and a drive circuit including a first constant voltage generation circuit, a second constant voltage generation circuit, and an output node, wherein the output circuit includes first and second n-channel insulated-gate field-effect transistors connected to each other in series, and a first p-channel insulated-gate field-effect transistor, a drain of the first n-channel insulated-gate field-effect transistor being connected to a first line, a source of the first n-channel insulated-gate field-effect transistor being connected to the output node, a back gate of the first n-channel insulated-gate field-effect transistor being connected to the source, a drain of the second n-channel insulated-gate field-effect transistor being connected to the output node, a source of the second n-channel insulated-gate field-effect transistor being connected to a second line, a back gate of the second n-channel insulated-gate field-effect transistor being connected to the source of the second n-channel insulated-gate field-effect transistor, a source of the first p-channel insulated-gate field-effect transistor being connected to the first line, a drain of the first p-channel insulated-gate field-effect transistor being connected to the output node, a back gate of the first p-channel insulated-gate field-effect transistor being connected to the source of the first p-channel insulated-gate field-effect transistor, and wherein the drive circuit further includes a second p-channel insulated-gate field-effect transistor, a third n-channel insulated-gate field-effect transistor, a capacitor, and a CMOS inverter, one end of the first constant voltage generation circuit is connected to one end of the second constant voltage generation circuit, another end of the first constant voltage generation circuit is connected to one end of the capacitor, and the CMOS inverter is connected between the first and second lines, a source of the second p-channel insulated-gate field-effect transistor being connected to the first line, a drain of the second p-channel insulated-gate field-effect transistor is connected to a drain of the third n-channel insulated-gate field-effect transistor, to an input terminal of the CMOS inverter, and to a gate of the first n-channel insulated-gate field-effect transistor, a gate of the second p-channel insulated-gate field-effect transistor being connected to the one end of the capacitor, a source of the third n-channel insulated-gate field-effect transistor being connected to the second line, a gate of the third n-channel insulated-gate field-effect transistor being connected to a different end of the capacitor, the input node being connected to any one of the gate of the second p-channel insulated-gate field-effect transistor and the gate of the third n-channel insulated-gate field-effect transistor, an output terminal of the CMOS inverter being connected to a gate of the second n-channel insulated-gate field-effect transistor and a gate of the first p-channel insulated-gate field-effect transistor, another end of the second constant voltage generation circuit being connected to the first line.

Further another aspect of the present invention provides a semiconductor device, which includes an input node, a plurality of voltage output circuits, third and fourth constant voltage generation circuits and an output node, each of the voltage output circuits including an output circuit and a drive circuit having first and second constant voltage generation circuits, wherein the output circuit includes a first p-channel insulated-gate field-effect transistor and first and second n-channel insulated-gate field-effect transistors connected to each other in series, a drain of the first n-channel insulated-gate field-effect transistor being connected to a first line, a source of the first n-channel insulated-gate field-effect transistor being connected to the output node, a back gate of the first n-channel insulated-gate field-effect transistor being connected to the source, a drain of the second n-channel insulated-gate field-effect transistor being connected to the output node, a source of the second n-channel insulated-gate field-effect transistor being connected to a second line, a back gate of the second n-channel insulated-gate field-effect transistor being connected to the source of the second n-channel insulated-gate field-effect transistor, a source of the first p-channel insulated-gate field-effect transistor being connected to the first line, a drain of the first p-channel insulated-gate field-effect transistor being connected to the output node, a back gate of the first p-channel insulated-gate field-effect transistor being connected to the source of the first p-channel insulated-gate field-effect transistor, wherein the drive circuit further includes a second p-channel insulated-gate field-effect transistor, a third n-channel insulated-gate field-effect transistor, first and second capacitors, and a CMOS inverter, one end of the first constant voltage generation circuit is connected to one end of the third constant voltage generation circuit, another end of the first constant voltage generation circuit is connected to one end of the first capacitor, the CMOS inverter is connected between the first and second lines, a source of the second p-channel insulated-gate field-effect transistor is connected to the first line, a drain of the second p-channel insulated-gate field-effect transistor being connected to a drain of the third n-channel insulated-gate field-effect transistor, to an input terminal of the CMOS inverter, and to a gate of the first n-channel insulated-gate field-effect transistor, a gate of the second p-channel insulated-gate field-effect transistor being connected to the one end of the first capacitor, and wherein a source of the third n-channel insulated-gate field-effect transistor is connected to the second line, a gate of the third n-channel insulated-gate field-effect transistor being connected to one end of the second capacitor and to one end of the second constant voltage generation circuit, one end of the fourth constant voltage generation circuit is connected to another end of the second constant voltage generation circuit, the input node is connected to other ends of the respective first and second capacitors, an output terminal of the CMOS inverter is connected to a gate of the second n-channel insulated-gate field-effect transistor and a gate of the first p-channel insulated-gate field-effect transistor, another end of the third constant voltage generation circuit is connected to the first line, and another end of the fourth constant voltage generation circuit is connected to the second line.

### BRIEF DESCRIPTION OF THE DRAWINGS

FIG. 1 is a circuit diagram showing a voltage output circuit of a semiconductor device according to a first embodiment of the invention.

FIG. 2 is a diagram showing a section of a principal portion of the semiconductor device according to the first embodiment.

FIG. 3 is a graph showing input/output characteristics of the voltage output circuit of the semiconductor device according to the first embodiment.

FIG. 4 is a circuit diagram showing a voltage output circuit of a semiconductor device according to a second embodiment of the invention.

FIG. 5 is a circuit diagram showing a voltage output circuit of a semiconductor device according to a third embodiment of the invention.

FIG. 6 is a circuit diagram showing a voltage output circuit of a semiconductor device according to a fourth embodiment of the invention.

FIGS. 7A and 7B are circuit diagrams, each of which includes constant voltage generation circuits other than those used in the semiconductor device according to the first embodiment.

FIG. 8 is a circuit diagram showing a voltage output circuit of a semiconductor device according to a fifth embodiment of the invention.

FIG. 9 is a circuit diagram showing a voltage output circuit of a semiconductor device according to a sixth embodiment of the invention.

### DETAILED DESCRIPTION OF THE PREFERRED EMBODIMENTS

Hereinafter, embodiments of the invention will be described with reference to the drawings. In the drawings, the same reference numerals denote the same portions respectively.

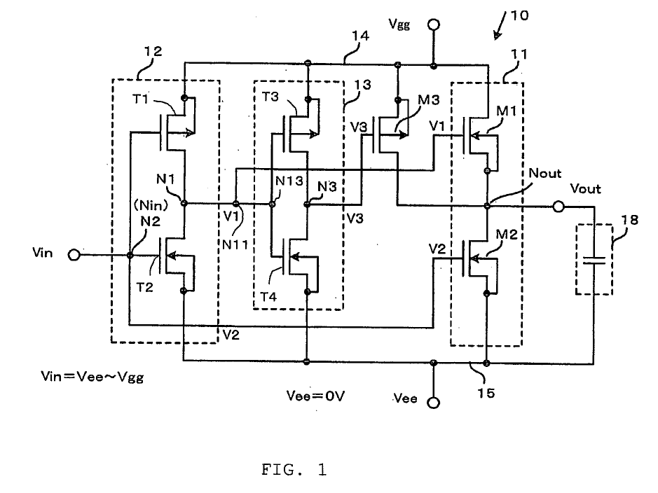

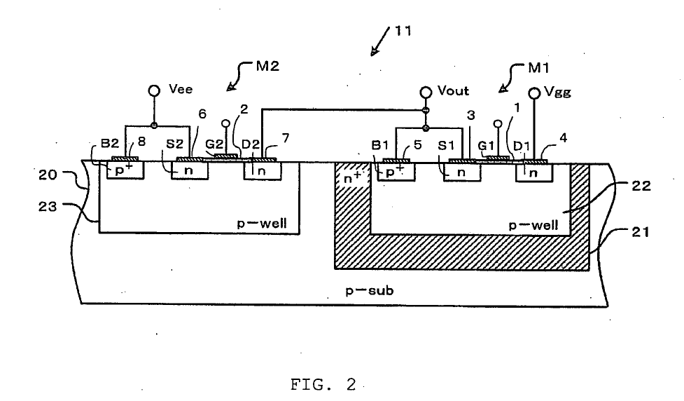

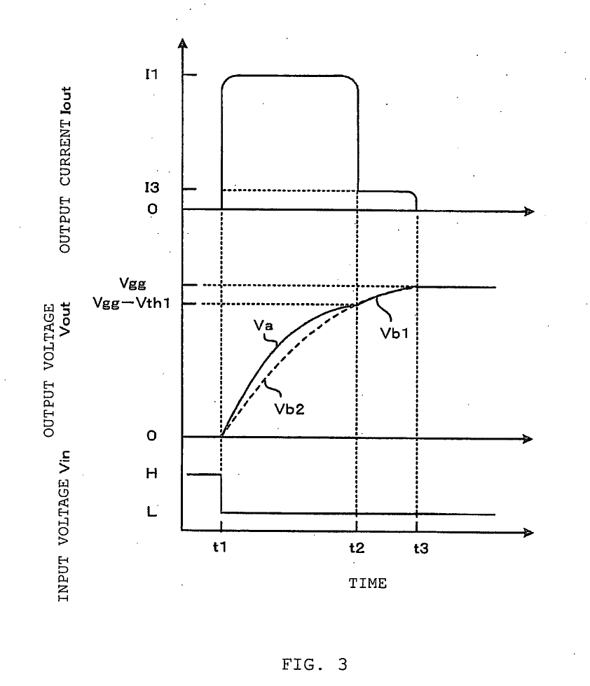

A first embodiment of a semiconductor device according to the invention will be described with reference to FIGS. 1 to 3. FIG. 1 is a circuit diagram showing a configuration of a voltage output circuit according to the first embodiment. FIG. 2 shows a section of a principal portion of the semiconductor device according to the first embodiment. FIG. 3 shows input/output characteristics of the voltage output circuit of the semiconductor device according to the first embodiment.

As shown in FIG. 1, a voltage output circuit 10 of the embodiment is provided with an output circuit 11 and a drive circuit 12.

The output circuit 11 includes a first n-channel insulated-gate field-effect transistor (hereinafter, referred to as “n-MOS transistor”) M1 having a triple well structure, and a second n-MOS transistor M2. The first n-MOS transistor M1 and the second n-MOS transistor M2 are connected in series. The drive circuit 12 includes a p-MOS transistor T1 and an n-MOS transistor T2. The drive circuit 12 includes nodes N1, N2. The drive circuit 12 is a CMOS inverter. The drive circuit 12 turns ON or turns OFF the first n-MOS transistor M1 and the second n-MOS transistor M2 in a complementary manner, in response to an input signal Vin.

The voltage output circuit 10 further includes a third p-channel insulated-gate field-effect transistor (hereinafter, referred to as “p-MOS transistor”) M3, and a CMOS inverter 13. The CMOS inverter 13 is provided with a p-MOS transistor T3, and an n-MOS transistor T4. The CMOS inverter 13 includes nodes N13, N3. The CMOS inverter 13 turns ON and OFF the p-MOS transistor M3, in response to turning ON and OFF of the first n-MOS transistor M1. The p-MOS transistor M3 is connected to the first n-MOS transistor M1 in parallel.

A drain of the first n-MOS transistor M1 is connected to a first line 14 to which a first electric potential is applied. A source of the first n-MOS transistor M1 is connected to an output node Nout. A gate of the first n-MOS transistor M1 is connected to the node N1. A back-gate (a p-well region to be described later) of the first n-MOS transistor M1 is connected to a source of the third p-MOS transistor M3.

A drain of the second n-MOS transistor M2 is connected to the output node Nout. A source of the second n-MOS transistor M2 is connected to a second line 15 to which a second electric potential lower than the first electric potential is applied. A gate of the second n-MOS transistor M2 is connected to the node N2. A back-gate (a p-well region to be described later) of the second n-MOS transistor M2 is connected to the source of the third p-MOS transistor M3.

The source of the p-MOS transistor M3 is connected to the drain of the first n-MOS transistor M1. A drain of the p-MOS transistor M3 is connected to the source of the first n-MOS transistor M1. A gate of the p-MOS transistor M3 is connected to the node N3. A back-gate (an n-well region to be described later) of the p-MOS transistor M3 is connected to the source of the p-MOS transistor M3.

A drain of the p-MOS transistor T1 and a drain of the n-MOS transistor T2 are connected to the node N1. A gate of the p-MOS transistor T1 and a gate of the n-MOS transistor T2 are connected to the node N2. A source of the p-MOS transistor T1 is connected to a back-gate (an n-well regions to be described later) of the p-MOS transistor T1 and the first line 14. A source of the n-MOS transistor T2 is connected to a back-gate (one of the p-well regions to be described later) of the n-MOS transistor T2 and the second line 15.

A drain of the p-MOS transistor T3 and a drain of the n-MOS transistor T4 are connected to the node N3. A gate of the p-MOS transistor T3 and a gate of the n-MOS transistor T4 are connected to the node N13. The node N13 and the node N1 are connected to a node N11.

A source of the p-MOS transistor T3 is connected to a back-gate (an n-well region to be described later) of the p-MOS transistor T3 and the first line 14. A source of the n-MOS transistor T4 is connected to a back-gate (a p-well region to be described later) of the n-MOS transistor T4 and the second line 15.

The first line 14 is connected to a power supply (not shown) to supply a higher supply voltage Vgg. The second line 15 is connected to a power supply (not shown) to supply a lower supply voltage Vee. The higher supply voltage Vgg is 45V, for example, and the lower supply voltage Vee is 0 V (GND), for example.

An output node of the drive circuit 12 is the node N1. An input node of the drive circuit 12 is the node N2. Control signals V1, V2, V3 are provided to the voltage output circuit 10, in response to an input signal Vin.

When the higher supply voltage Vgg is 45 V, the input signal Vin needs to be 0 V to 45 V to drive the drive circuit 12. Accordingly, in order to drive the drive circuit 12 using a lower voltage of 0 V to 3 V for the input signal Vin, for example, it is necessary to have a level shift circuit (not shown) to shift the voltage level of the input signal Vin from the lower voltage of 0 V to 3 V to the higher voltage of 0 V to 45 V.

When the input signal Vin is at a low level (hereinafter, referred to as “L level”), the control signal V1 becomes a high level (hereinafter, referred to as “H level”), and the control signal V2 becomes the L level. Accordingly, the first n-MOS transistor M1 is turned ON, and the second n-MOS transistor M2 is turned OFF.

When the input signal Vin is at the H level, the control signal V1 becomes the L level, and the control signal V2 becomes the H level. As a result, the first n-MOS transistor M1 is turned OFF, and the second n-MOS transistor M2 is turned ON.

Hence, the first n-MOS transistor M1 and the second n-MOS transistor M2 are turned ON or OFF in a complementary manner in response to the input signal Vin.

When the first n-MOS transistor M1 is turned ON and when the second n-MOS transistor M2 is turned OFF, the output signal Vout of the output circuit 11a is a voltage which is obtained by subtracting a voltage drop of the first n-MOS transistor M1 from the higher supply voltage Vgg.

The output signal Vout is outputted to a capacitive load 18, for example, from the output node Nout. When the first n-MOS transistor M1 is turned OFF and when the second n-MOS transistor M2 is turned ON, the output signal Vout is 0 V.

Since the first n-MOS transistor M1 has a triple well structure, the output signal Vout can not decrease due to a back-gate bias effect of the first n-MOS transistor M1 which is caused by a substrate voltage Vbs. The output signal Vout is represented by a difference between the higher supply voltage Vgg and a threshold voltage Vth1 of the first n-MOS transistor M1, as expressed by the following formula.

Vout≡Vgg−Vbs−Vth1=Vgg−Vth1 (1)

FIG. 2 shows a section of a principal portion of the output circuit 11 where the first n-MOS transistor M1 and the second n-MOS transistor M2 of the voltage output circuit 10 are connected in series.

As shown in FIG. 2, the first and second n-MOS transistors M1, M2 are formed to be integrated monolithically on a p-type silicon substrate 20.

An n-type well region 21 and a p-type well region 23 are formed on the p-type silicon substrate 20 so as to be separated from each other. A p-type well region 22 is formed in the n-type well region 21. An n-type source region S1, an n-type drain region D1, and a p-type high-impurity-concentration region B1 of the first n-MOS transistor M1 are formed in the p-type well region 22. A gate insulating film 1 is provided on a semiconductor region formed between the source region S1 and the drain region D1. A gate electrode G1 is formed on the gate insulating film 1. Electrodes 3, 4, 5 are respectively formed on the source region S1, the drain region D1, and the high-impurity-concentration region B1.

The first n-MOS transistor M1 has the triple well structure. The source region S1 and the p-type high-impurity-concentration region B1 are connected to the output node Vout. The higher supply voltage Vgg is applied to the drain region D1.

An n-type source region S2, an n-type drain region D2, and a p-type high-impurity-concentration region B2 of the second n-MOS transistor M2 are formed in the p-type well region 23. A gate insulating film 2 is provided on a semiconductor region formed between the source region S2 and the drain region D2. A gate electrode G2 is formed on the gate insulating film 2. Electrodes 6, 7, 8 are respectively formed on the source region S2, the drain region D2, and the high-impurity-concentration region B2. The lower supply voltage Vee is applied to the source region S2 and the p-type high-impurity-concentration region B2. The drain region D2 is connected to the output node Vout.

The source regions, the drain regions, and the high-impurity-concentration regions of the p-MOS transistors M3, T1, T3 are respectively formed in the foregoing n-type well regions (not shown). Gate electrodes are formed respectively on semiconductor regions formed between the source region and the drain region of the p-MOS transistor T1 and between the source region and the drain region of the p-MOS transistor T3.

The source regions, the drain regions, and the high-impurity-concentration regions of the n-MOS transistors T2, T4 are respectively formed in the foregoing p-type well regions (not shown). Gate electrodes are formed respectively above semiconductor regions formed between the source region and the drain region of the n-MOS transistor T2 and between the source region and the drain region of the n-MOS transistor T4. Insulating films are formed between the gate electrodes and the semiconductor regions respectively

The p-type well region 22, in which the first n-MOS transistor M1 is formed, is electrically insulated from the p-type silicon substrate 20 by the n-type well region 21. Accordingly, the electric potential of the p-type well region 22 is not affected by variation in the electric potential of the p-type silicon substrate 20.

The p-type well region 22, which is a back gate of the first n-MOS transistor M1, is connected to the source region S1 of the first n-MOS transistor M1. Accordingly, decrease of drain current due to the back-gate bias effect can be suppressed. As a result, the drop voltage Vbs due to the back-gate bias effect may be cancelled. As shown in the foregoing formula (1), the output signal Vout of the first n-MOS transistor M1 is not decreased due to the back-gate bias effect.

Further, when the input signal Vin of FIG. 1 is at the L level, the control signal V3 from the node N3 becomes the L level. Accordingly, the p-MOS transistor M3 is turned ON, and consequently a short circuit occurs between the source region S1 and the drain region D1 of the first n-MOS transistor M1. When the input signal Vin is at the H level, the control signal V3 from the node N3 becomes the H level. Accordingly, the p-MOS transistor M3 is turned OFF, and consequently the p-MOS transistor M3 is electrically isolated from the first n-MOS transistor M1.

When the p-channel p-MOS transistor M3 is turned ON, a drain voltage of the p-MOS transistor M3 becomes approximately equal to the higher supply voltage Vgg. Accordingly, the first n-MOS transistor M1 is short-circuited, and decrease of the output signal Vout due to the threshold voltage Vth1 may be cancelled. As a result, the output signal Vout from the output node Nout is expressed by the following formula.

Vout≡Vgg−Vbs−Vth1=Vgg (2)

Referring to FIG. 3, input/output characteristics of the semiconductor device shown in FIGS. 1, 2 will be described.

As shown in FIG. 3, the input signal Vin becomes the L level at time t=t1. As a result, the first n-MOS transistor M1 is turned ON, while the second n-MOS transistor M2 is turned OFF. Accordingly, the drain voltage of the first n-MOS transistor M1 rises. As a result, the output signal Vout increases as shown by a solid voltage curve Va in FIG. 3.

Similarly, the p-MOS transistor M3 is also turned ON. Accordingly, the drain voltage of the p-MOS transistor M3 rises. As a result, the output signal Vout increases as shown by a dotted voltage curve Vb2 in FIG. 3.

Since the p-MOS transistor M3 is p-channel, a response speed of the p-MOS transistor M3 is lower than that of the first n-MOS transistor M1. For this reason, the voltage Vb2 increases at a slower rate than the voltage Va.

The voltage shown by the voltage curve Va represents the output signal Vout. Accordingly, a drain current I1 of the first n-MOS transistor M1 becomes an output current lout as shown in FIG. 3 to charge the capacitive load 18.

When the output signal Vout reaches Vgg-Vth1 at t=t2, the voltage increase shown by the voltage curve Va terminates, and the drain current I1 becomes zero.

When the drain voltage of the p-MOS transistor M3 shown by the voltage curve Vb2 catches up with the drain voltage of the first n-MOS transistor M1 shown by the voltage curve Va, the output signal Vout increases along a solid voltage curve Vb1.

The voltage shown by the voltage curve Vb1 represents the output signal Vout. Accordingly, a source current I3 of the p-MOS transistor M3 becomes the output current Iout, and additionally charges the capacitive load 18.

The p-MOS transistor M3 has lower current drivability than the first n-MOS transistor M1 so that the current I3 is lower than the current I1.

When the voltage shown by the voltage curve Vb1 reaches the higher supply voltage Vgg at t=t3, the voltage increase shown by the voltage curve Vb1 terminates, and the output signal Vout remains at the higher supply voltage Vgg. The capacitive load 18 is fully charged, and the output signal Vout becomes zero.

The voltage output circuit according to this embodiment may have following characteristics. One of the characteristics is high current drivability, which the first n-MOS transistor M1 shows. Another one of the characteristics is low voltage reduction characteristic, which the p-MOS transistor M3 shows.

As described above, the semiconductor device 10 of this embodiment includes the p-MOS transistor M3 and the output circuit 11, which has the first and second n-MOS transistors M1, M2. The first n-MOS transistor M1 has the triple well structure. The first n-MOS transistor M1 and the second n-MOS transistor M2 are connected in series. The p-MOS transistor M3 and the first n-MOS transistor M1 are connected in parallel.

As a result, decrease of the output voltage, which is caused by the back-gate bias effect of the first n-MOS transistor M1, may be cancelled. Further, decrease of the output voltage, which is caused by the threshold voltage Vth1 of the first n-MOS transistor M1, can be cancelled.

Accordingly, the voltage output circuit 10 can show high current drivability and small voltage decrease.

For the first n-MOS transistor M1 of the above embodiment, a MOS transistor having a triple well structure has been used. However, the first n-MOS transistor M1 does not always need to have a triple well structure. the first n-MOS transistor M1 may be a MOS transistor formed in a p-type well region of a p-type silicon substrate.

When the first n-MOS transistor M1 does not have a triple well structure, the output signal Vout is decreased by the substrate voltage Vbs caused due to the back-gate bias effect caused in the first n-MOS transistor M1. Thus, power consumption increases.

In this case, the first n-MOS transistor M1 is short-circuited by the p-MOS transistor M3. Accordingly, voltage reductions caused by the substrate voltage Vbs and the threshold voltage Vth1 may be cancelled. Consequently, the output signal Vout of the output node Nout can be prevented from being affected by the voltage reductions.

In the above embodiment, the second n-MOS transistor M2 and the third p-MOS transistor M3 are normal MOS transistors respectively formed in the p-type well region and the n-type well region of the p-type silicon substrate. The second n-MOS transistor M2 and the third p-MOS transistor M3 may have triple well structures respectively as the first n-MOS transistor M1.

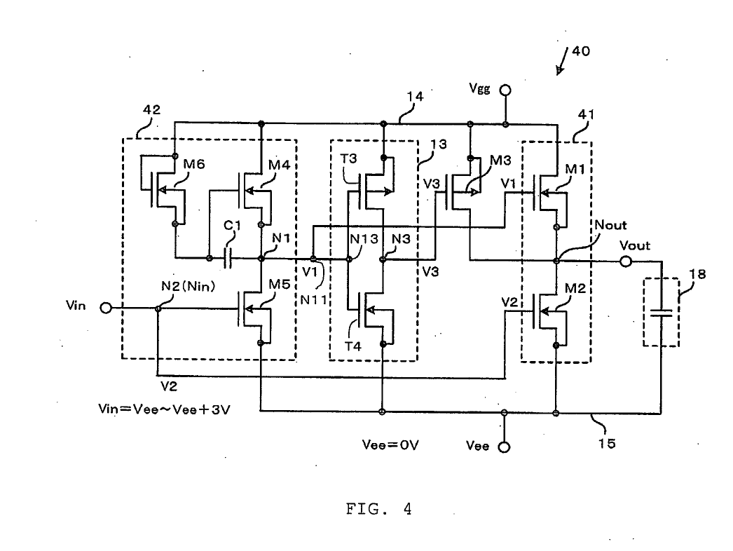

FIG. 4 is a circuit diagram showing a configuration of a voltage output circuit of a semiconductor device according to a second embodiment of the invention.

The semiconductor device of this embodiment is configured so that a first n-MOS transistor and a second n-MOS transistor may be driven by a lower voltage input signal.

As shown in FIG. 4, a voltage output circuit 40 of the semiconductor device of this embodiment is provided with an output circuit 41 and a drive circuit 42. The output circuit 41 includes first and second n-MOS transistors M1, M2 connected in series. The first n-MOS transistor M1 has a triple well structure. The second n-MOS transistor M2 has a thin gate structure having a gate insulating film thinner than that of the first n-MOS transistor M1.

The drive circuit 42 drives the first n-MOS transistor M1 with a control signal V1 of high voltage in response to a lower voltage input signal Vin. The drive circuit 42 drives the second n-MOS transistor M2 with a control signal V2 of lower voltage in response to the lower voltage input signal Vin.

The drive circuit 42 is a bootstrap circuit. The drive circuit 42 includes an n-MOS transistor M4 having a triple well structure, an n-MOS transistor M5 having a thin film gate structure, an n-MOS transistor M6 having a triple well structure, and a capacitor C1. “An n-MOS transistor having a thin film gate structure” is an n-MOS transistor which has a lower gate-to-source voltage Vgs and a higher drain-to-source voltage Vds, and which has sufficient current drivability.

A drain of the n-MOS transistor M4 is connected to a first line 14. A source of the n-MOS transistor M4 is connected to a node N1. A gate of the n-MOS transistor M4 is connected to the node N1 with the capacitor C1 interposed between the gate of the n-MOS transistor M4 and the node N1.

A drain of the n-MOS transistor M5 is connected to the node N1. A source of the n-MOS transistor M5 is connected to a second line 15. A gate of the n-MOS transistor M5 is connected to an input node N2.

A drain of the n-MOS transistor M6 is connected to the first line 14. A source of the n-MOS transistor M6 is connected to the node N1 with the capacitor C1 interposed between the source of the n-MOS transistor M6 and the node N1. A gate of the n-MOS transistor M6 is connected to the drain of the n-MOS transistor M6.

When the lower voltage input signal Vin becomes a L level, the second n-MOS transistor M2 is turned OFF, and the n-MOS transistor M5 is also turned OFF. Accordingly, the capacitor C1 is charged via the n-MOS transistor M6 serving as an active load.

When a terminal voltage of the capacitor C1 exceeds a threshold voltage Vth4 of the n-MOS transistor M4, the n-MOS transistor M4 is turned ON. As a result, the control signal V1 becomes a H level, and the first n-MOS transistor M1 is turned ON.

When the input signal Vin becomes a H level, the second n-MOS transistor M2 is turned ON, and the n-MOS transistor M5 is also turned ON. Accordingly, the control signal V1 is reduced to the L level so that the first n-MOS transistor M1 is turned OFF.

Charges accumulated in the capacitor C1 are discharged via the n-MOS transistor M5. When the terminal voltage of the capacitor C1 falls below the threshold voltage Vth4 of the n-MOS transistor M4, the n-MOS transistor M4 is substantially turned OFF. However, since the n-MOS transistor M4 is not completely turned OFF, electric current constantly flows through the n-MOS transistor M4.

With such a structure, the first and second n-MOS transistors M1, M2 can be turned ON or OFF in a complementary manner in accordance with levels of the lower voltage input signal Vin, which is 0 V to 3 V, for example.

In the voltage output circuit 40 of the semiconductor device according to this embodiment, the second n-MOS transistor M2 has a thin film gate structure, and the drive circuit 42 is a bootstrap circuit.

The voltage output circuit 40 can be directly driven by the lower voltage input signal Vin. Therefore, there is an advantage that the level shift circuit is not always necessary so that a chip size of a semiconductor device including the voltage output circuit 40 may be reduced.

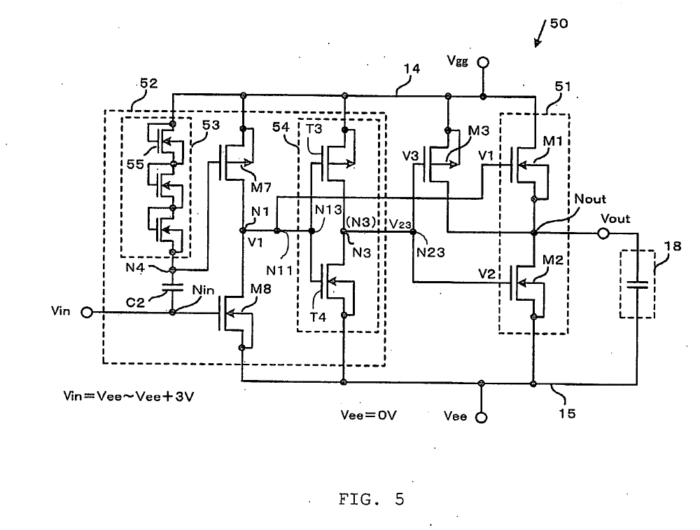

FIG. 5 is a circuit diagram showing a configuration of a voltage output circuit of a semiconductor device according to a third embodiment of the invention.

The semiconductor device of this embodiment is configured so that first and second n-MOS transistors may be driven by a lower voltage input signal.

As shown in FIG. 5, a voltage output circuit 50 of the semiconductor device of the embodiment includes an output circuit 51 and a drive circuit 52. The output circuit 51 is provided with a first n-MOS transistor M1 having a triple well structure and a second n-MOS transistor M2 having a high withstand voltage. The first and second n-MOS transistors M1, M2 are connected in series.

The drive circuit 52 drives the first n-MOS transistor M1 with a control signal V1 of high voltage in response to a lower voltage input signal Vin. The drive circuit 52 drives the second n-MOS transistor M2 with a control signal V2 of high voltage in response to a lower voltage input signal Vin.

The drive circuit 52 is provided with a constant voltage generation circuit 53, a second capacitor C2, a p-MOS transistor M7, an n-MOS transistor M8 and a CMOS inverter 54.

One end of the constant voltage generation circuit 53 is connected to a first line 14. The other end of the constant voltage generation circuit 53 is connected to a node N4. One end of the second capacitor C2 is connected to the node N4. The other end of the second capacitor C2 is connected to an input node Nin. A source of the p-MOS transistor M7 is connected to the first line 14. A drain of the p-MOS transistor M7 is connected to a node N1. A gate of the p-MOS transistor M7 is connected to the node N4.

A drain of the n-MOS transistor M8 is connected to the node N1. A source of the n-MOS transistor M8 is connected to a second line 15. A gate of the n-MOS transistor M8 is connected to the input node Nin. The CMOS inverter 54 includes a p-MOS transistor T3 and an n-MOS transistor T4 connected in series. The CMOS inverter 54 is connected between the first line 14 and the second line 15. A node N13, which is an input terminal of the CMOS inverter 54, is connected to the node N1 via a node 11. A node N3, which is an output terminal of the CMOS inverter 54, is connected to a node N23.

The constant voltage generation circuit 53 includes three n-MOS transistors 55, for example, connected in series to each other. Gates of the n-MOS transistors 55 and drains of the n-MOS transistors 55 are respectively connected. The constant voltage generation circuit 53 generates a constant voltage that is about three times higher than a threshold voltage Vth55 of the n-MOS transistors 55. When Vth55=1 V, for example, the constant voltage of the constant voltage generation circuit 53 may be 3 V.

A voltage Vn4 of the node N4 is generally expressed by the following formula. C3 denotes a gate capacity of the p-MOS transistor M7.

Vn4=(Vin−Vee)/(1+C3/C2)+Vgg−3Vth55 (3)

The lower voltage input signal Vin is from 0 V to 3 V, for example. When the lower voltage input signal Vin becomes the L level, the n-MOS transistor M8 is turned OFF. The second capacitor C2 is charged via the constant voltage generation circuit 53 serving as an active load. As a result, the voltage Vn4 of the node N4 becomes Vgg−3Vth55. The gate of the p-MOS transistor M7 is negatively biased with respect to the source of the p-MOS transistor M7 so that the p-MOS transistor M7 is turned ON.

An electric potential of the node N1 rises, and the control signal V1 becomes the H level. Thus, a control signal V23 is made to have the L level by the CMOS inverter 54. As a result, the first n-MOS transistor M1 is turned ON, and the second n-MOS transistor M2 is turned OFF.

Once the lower voltage input signal Vin becomes the H level, the n-MOS transistor M8 is turned ON. When the H level is 3 V, for example, the node N4 transitions to an open state, and the second capacitor C2 is electrically isolated from the node N4. A gate voltage of the p-MOS transistor M7 becomes Vgg. The p-MOS transistor M7 is turned OFF.

The first n-MOS transistor M1 and the second n-MOS transistor M2 can be turned ON or OFF in a complementary manner in response to the lower voltage input signal Vin.

A voltage applied between each two of electrodes of the n-MOS transistors 55 is lower than that applied between each two of electrodes of the second n-MOS transistor M2. Accordingly, withstand voltages applied between each two of electrodes of each n-MOS transistor 55, i.e., a drain-source withstand voltage, a gate-source withstand voltage, and a gate-drain withstand voltage, are set so as to be lower than a withstand voltage between each two of electrodes of the second n-MOS transistor M2 respectively. The n-MOS transistors 55 are MOS transistors which operate at lower voltages.

Each of such n-MOS transistors has a gate oxide film thinner than that of the second n-MOS transistor M2, has a smaller size, and has higher current drivability.

As described above, in accordance with the voltage output circuit 50 of the semiconductor device of the embodiment, the drive circuit 52 generates a gate voltage of the p-MOS transistor M7 by the constant voltage generation circuit 53 and the second capacitor C2 connected in series, in response to the lower voltage input signal Vin.

As a result, the p-MOS transistor M7 and the n-MOS transistor M8 can be turned ON or OFF in a complementary manner by the lower voltage input signal Vin. Accordingly, electric current can be suppressed to a small value, as compared to a case where the drive circuit using a bootstrap circuit is used.

In the above-described embodiment, the constant voltage generation circuit 53 is formed of the three n-MOS transistors 55. The number of the n-MOS transistors 55 may be suitably determined, when necessary. Instead of the n-MOS transistors 55, a series circuit using pn junction diodes, or a series circuit using p-MOS transistors may be used.

In the case where the p-MOS transistors are employed, it is possible to use MOS transistors to operate at lower voltages. Each of the MOS transistors may have a withstand voltage between each two electrodes of the MOS transistors, which is lower than that applied between each two electrodes of the p-MOS transistor M3.

Not all the MOS transistors constituting the constant voltage generation circuit 53 need to be MOS transistors to operate at lower voltages. At least one MOS transistor needs to be a MOS transistor to operate at a lower voltage.

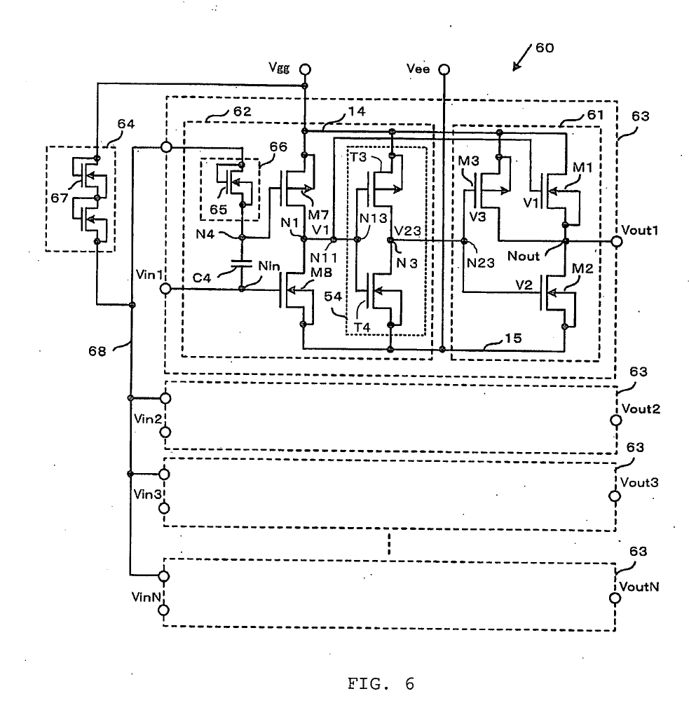

FIG. 6 is a circuit diagram showing a configuration of a voltage output circuit of a semiconductor device according to a fourth embodiment of the invention.

In this embodiment, multiple voltage output circuits 50 of the third embodiment are integrated, and multiple input/output nodes are provided. The embodiment is applied to ICs for a gate driver to drive pixel transistors of thin film transistor (TFT) liquid crystal panels, for example.

As shown in FIG. 6, a voltage output circuit 60 of the semiconductor device of the embodiment is provided with multiple voltage output circuits 63 and a second constant voltage generation circuit 64. The voltage output circuits 63 receive input signals Vin1 to VinN, and provide output signals Vout1 to VoutN respectively.

Each of the multiple voltage output circuits 63 includes an output circuit 61 outputting higher voltage, and includes a drive circuit 62. Each drive circuit 62 drives the corresponding one of the output circuits 61 by an input signal Vin of lower voltage (2 to 3 V higher than a lower supply voltage Vee, for example). The second constant voltage generation circuit 64 is used for charging a capacitor C4 of each drive circuit 62.

The output circuit 61 includes first and second n-MOS transistors M1, M2, and a p-MOS transistor M3.

A drain of the first n-MOS transistor M1 is connected to a first line 14. A source of the first n-MOS transistor M1 is connected to an output node Nout. A gate of the first n-MOS transistor M1 is connected to a node N1. A back gate of the first n-MOS transistor M1 is connected to the source of the first n-MOS transistor M1.

A drain of the second n-MOS transistor M2 is connected to the output node Nout. A source of the second n-MOS transistor M2 is connected to a second line 15 lower than a first electric potential. A gate of the second n-MOS transistor M2 is connected to a node N23. A back gate of the second n-MOS transistor M2 is connected to the source of the second n-MOS transistor M2.

A source of the p-MOS transistor M3 is connected to the first line 14. A drain of the p-MOS transistor M3 is connected to the output node Nout. A gate of the p-MOS transistor M3 is connected to a node N3. A back gate of the p-MOS transistor M3 is connected to the source of the p-MOS transistor M3.

The drive circuit 62 is provided with a first constant voltage generation circuit 66, a capacitor C4, a p-MOS transistor M7, an n-MOS transistor M8 and a CMOS inverter 54.

The first constant voltage generation circuit 66 includes an n-MOS transistor 65. A gate of the n-MOS transistor 65 and a drain of the n-MOS transistor 65 are connected to each other. A source of the n-MOS transistor 65 is connected to a node N4. One end of the capacitor C4 is connected to the node N4. The other end of the capacitor C4 is connected to an input node Nin.

A source of the p-MOS transistor M7 is connected to the first line 14. A drain of the p-MOS transistor M7 is connected to the node N1. A gate of the p-MOS transistor M7 is connected to the node N4.

A drain of the n-MOS transistor M8 is connected to the node N1. A source of the n-MOS transistor M8 is connected to the second line 15. A gate of the n-MOS transistor M8 is connected to the input node Nin. The CMOS inverter 54 is connected between the first line 14 and the second line 15. The CMOS inverter 54 includes a p-MOS transistor T3 and an n-MOS transistor T4 connected in series to each other.

An input terminal N13 of the CMOS inverter 54 is connected to the node N1 via a node N11. The output terminal N3 of the CMOS inverter 54 is connected to the node N23.

The drive circuit 62 outputs control signals V1, V23 from the nodes N1, N3 in response to an input signal Vin supplied to the input node Nin. The control signals V1, V23 turn ON or OFF the first and second n-MOS transistors M1, M2 in a complementary manner respectively. The control signal V23 is an inverted signal of the control signal V1.

The second constant voltage generation circuit 64 includes n-MOS transistors 67 connected in series. A gate and a drain of each n-MOS transistor 67 are connected to each other. One end of a series circuit including the n-MOS transistors 67 is connected to the first line 14. The other end of the series circuit is connected to an interconnection 68. The interconnection 68 is connected in common to the other ends of the respective first constant voltage generation circuits 66.

When the input signal Vin becomes a L level, the n-MOS transistor M8 is turned OFF. The capacitor C4 is charged via the first constant voltage generation circuit 66 and the second constant voltage generation circuit 64, which are connected in series and serve as active loads. Since a voltage Vn4 of the node N4 becomes Vgg−(Vth65+2Vth67), the gate of the p-MOS transistor M7 is negatively biased with respect to the source of the p-MOS transistor M7. As a result, the p-MOS transistor M7 is turned ON. Other operations of the voltage output circuit 63 are the same as those of the third embodiment.

In the voltage output circuit 60, the two constant voltage generation circuit 64, 66 serve as active loads and charge the capacitor C4. Further, the first constant voltage generation circuit 66, which is composed of one MOS transistor (the MOS transistor 65), is disposed in the drive circuit 62. Furthermore, the second constant voltage generation circuit 64, which is composed of two MOS transistors (the MOS transistors 67), is disposed outside the drive circuit 62. The second constant voltage generation circuit 64 is shared by the drive circuits 62.

When the voltage output circuit 60 is an IC for a gate driver to drive a TFT liquid crystal panel, the number N of the voltage output circuits 63 in the voltage output circuit 60 is from 200 to 540 in order to drive pixel transistors on scan lines.

The second constant voltage generation circuit 64 is connected in common to the voltage output circuits 63. Thus, the number of n-MOS transistors can be reduced by (2N−2) as compared to the case where second constant voltage generation circuits are respectively connected to the voltage output circuits 63. Therefore, it is possible to reduce the chip size of a semiconductor device including the voltage output circuit 60.

In this embodiment, the first and second constant voltage generation circuits 66, 64 are formed by the n-MOS transistors 65, 67. Instead of the n-MOS transistors 65, 67, p-MOS transistors may be used.

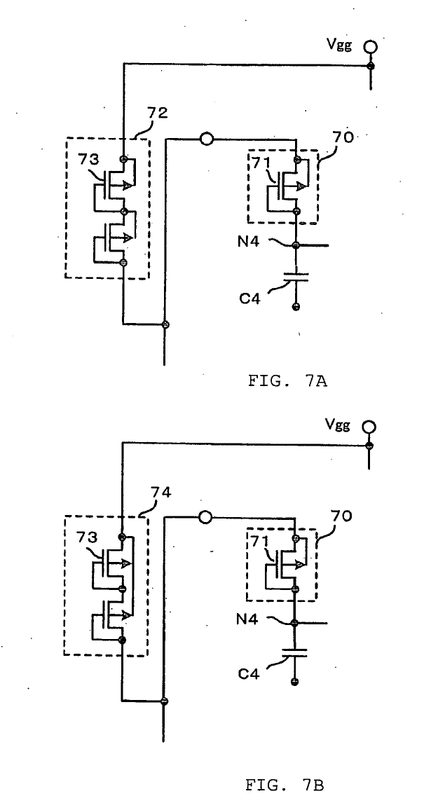

FIGS. 7A and 7B show examples of a circuit which is provided with first and second constant voltage generation circuits using p-MOS transistors.

In FIG. 7A, a first constant voltage generation circuit 70 includes a p-MOS transistor 71. A gate of the p-MOS transistor 71 is connected to a drain of the p-MOS transistor 71. A back gate of the p-MOS transistor 71 is connected to a source of the p-MOS transistor 71.

A second constant voltage generation circuit 72 includes a series circuit having multiple p-MOS transistors 73 connected to each other in series. A gate and a drain of each p-MOS transistor 73 are connected to each other. A back gate of the p-MOS transistor 73 is connected to a source of the p-MOS transistor 73.

The p-MOS transistors 71, 73 are not affected by variation in a threshold value caused due to the back-gate bias effect. Thus, decrease of output voltage of the output signals, which is caused by the first and second constant voltage generation circuits 70, 72, can be suppressed.

The p-MOS transistors 71, 73 have small current drivability as compared with n-MOS transistors, and thus are suitable when current to be charged to the capacitor C4 may be small.

In FIG. 7B, a configuration of the first constant voltage generation circuit 70 is as described in FIG. 7A. A second constant voltage generation circuit 74 is provided with p-MOS transistors 73 connected in series. A gate and a drain of each of the p-MOS transistors 73 are connected to each other. Back gates of the p-MOS transistors 73 are connected to a higher supply voltage Vgg.

The second constant voltage generation circuit 74 is affected by the variation in the threshold value which is caused due to a back-gate bias effect. However, the p-MOS transistors 73 of the second constant voltage generation circuit 74 do not need a contact area to allow an interconnection extending from the source to contact the back gate, unlike the p-MOS transistors of the second constant voltage generation circuit 72 in FIG. 7A. As such a contact area is unnecessary as described above, reduction in chip size may be attained for a semiconductor device including the voltage output circuit 60.

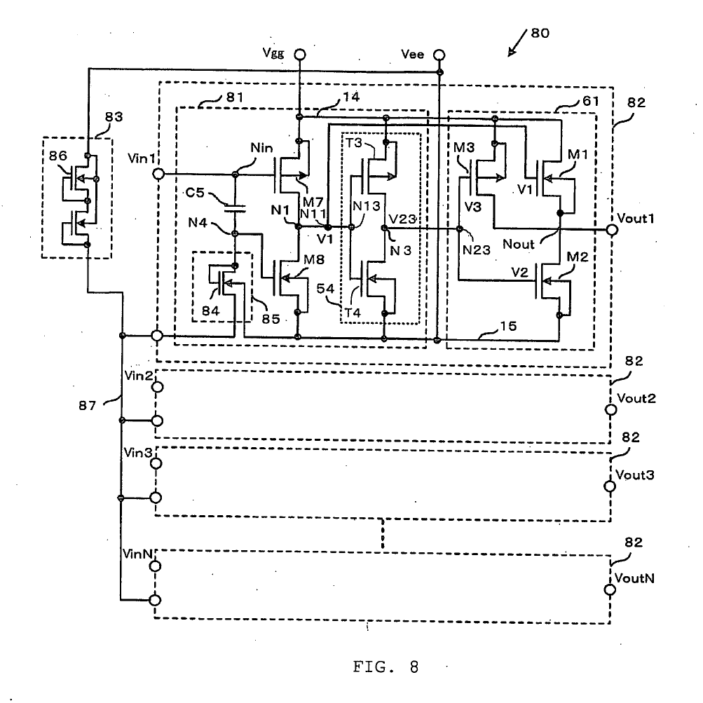

FIG. 8 is a circuit diagram showing a configuration of a voltage output circuit of a semiconductor device according to a fifth embodiment of the invention.

The semiconductor device of this embodiment is configured to drive an output circuit with a higher voltage input signal.

As shown in FIG. 8, a voltage output circuit 80 of the semiconductor device of the embodiment is provided with multiple output circuits 82 and a second constant voltage generation circuit 83. Each of the output circuits 82 includes an output circuit 61 outputting higher voltage, and includes a drive circuit 81.

Each of the drive circuits 81 drives corresponding one of the output circuits 61 by an input signal. The input signal may have a voltage 2 V to 3 V lower than a higher supply voltage Vgg, for example. The second constant voltage generation circuit 83 is used in common to charge a capacitor C5 of each of the drive circuits 81.

The drive circuit 81 is provided with a capacitor C5 and a first constant voltage generation circuit 85 including an n-MOS transistor 84. A gate and a drain of the n-MOS transistor 84 are connected to each other. One end of the first constant voltage generation circuit 85 is connected to a node N4. One end of the capacitor C5 is connected to the node N4. The other end of the capacitor C5 is connected to an input node Nin. A gate of a p-MOS transistor M7 is connected to the input node Nin. A gate of an n-MOS transistor M8 is connected to the node N4.

The second constant voltage generation circuit 83 includes multiple n-MOS transistors 86 connected in series to each other. A gate and a drain of each of the n-MOS transistors 86 are connected to each other. Back gates of the n-MOS transistors 86 are connected in common to lower supply voltage Vee. One end of the second constant voltage generation circuit 83 is connected to a second line 15. The other end of the second constant voltage generation circuit 83 is connected to an interconnection 87 connected in common to the other ends of the first constant voltage generation circuits 85.

When an input signal Vin becomes a H level, the p-MOS transistor M7 is turned OFF. The capacitor C5 is charged via the second constant voltage generation circuit 83 and the first constant voltage generation circuit 85 which are connected in series and serve as active loads.

As a result, a voltage Vn4 of the node N4 becomes Vee+(Vth84+2Vth86). Accordingly, the gate of the n-MOS transistor M8 is positively biased with respect to a source of the n-MOS transistor M, so that the n-MOS transistor M8 is turned ON. Other operations of the output circuits 82 are the same as those of the voltage output circuit 50 of the third embodiment.

As described above, the voltage output circuit 80 of the semiconductor device of this embodiment includes the multiple output circuits 82 and the second constant voltage generation circuit 83. The drive circuits 81 of the respective output circuits 82 are connected in common to the second constant voltage generation circuit 83. Therefore, the chip size of the semiconductor device can be reduced. Further, the voltage output circuit 80 can be driven by the input signal Vin with the voltage 2 V to 3 V lower than the higher supply voltage Vgg, for example.

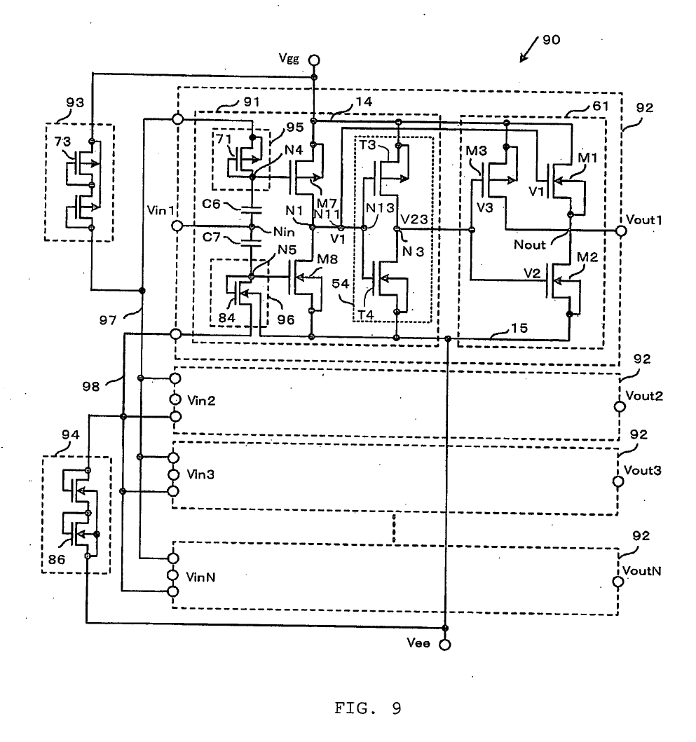

FIG. 9 is a circuit diagram showing a configuration of a voltage output circuit of a semiconductor device according to a sixth embodiment of the invention.

In this embodiment, an output circuit is driven by an input signal of logic potentials, without depending on a higher supply voltage Vgg and a lower supply voltage Vee.

As shown in FIG. 9, a voltage output circuit 90 of the semiconductor device of this embodiment is provided with multiple output circuits 92 and third and fourth constant voltage generation circuits 93, 94. Each of the output circuits 92 includes an output circuit 61 to output a higher voltage, and includes a drive circuit 91. The drive circuit 91 drives the output circuit 61 by an input signal Vin1 (or Vin2, . . . , or VinN) having logic potentials of Vdd≈3 V and Vss=0 V, for example. The third constant voltage generation circuit 93 is used to charge a capacitor C6 constituting each of the drive circuits 91. The fourth constant voltage generation circuit 94 is used to charge a second capacitor C7 constituting each of the drive circuits 91.

The drive circuit 91 is provided with a first constant voltage generation circuit 95 and a second constant voltage generation circuit 96. The first constant voltage generation circuit 95 includes a p-MOS transistor 71. A gate and a drain of the p-MOS transistor 71 are connected to each other. One end of the first constant voltage generation circuit 95 is connected to a node N4. One end of the capacitor C6 is connected to the node N4. The other end of the capacitor C6 is connected to an input node Nin.

The second constant voltage generation circuit 96 includes an n-MOS transistor 84. A gate and a drain of the n-MOS transistor 84 are connected to each other. One end of the second capacitor C7 is connected to a node N5. The other end of the second capacitor C7 is connected to the input signal Vin. A gate of a p-MOS transistor M7 is connected to the node N4. A gate of an n-MOS transistor M8 is connected to the node N5.

A configuration of the first constant voltage generation circuit 95 is the same as that of the first constant voltage generation circuit 70 shown in FIG. 7B. A configuration of the second constant voltage generation circuit 96 is the same as that of the first constant voltage generation circuit 85 shown in FIG. 8.

A configuration of the third constant voltage generation circuit 93 is the same as that of the second constant voltage generation circuit 74 shown in FIG. 7B. The other end of the third constant voltage generation circuit 93 is connected to a first interconnection 97 to connect the other ends of the respective multiple first constant voltage generation circuits 95.

A configuration of the fourth constant voltage generation circuit 94 is the same as that of the second constant voltage generation circuit 83 shown in FIG. 8. The other end of the fourth constant voltage generation circuit 94 is connected to a second interconnection 98 to connect the other ends of the respective multiple second constant voltage generation circuits 96.

The higher supply voltage Vgg is Vgg≈25 V, for example. The lower supply voltage Vee is Vee≈−15 V, for example.

When the input signal Vin becomes a L level, the node N4 becomes the L level, and the node N5 becomes the L level. Accordingly, the p-MOS transistor M7 is turned ON, and the n-MOS transistor M8 is turned OFF.

When the input signal Vin becomes a H level, the node N4 becomes the H level, and the node N5 becomes the H level. Accordingly, the p-MOS transistor M7 is turned OFF, and the n-MOS transistor M8 is turned ON.

It is assumed that a threshold Vthp of the p-MOS transistors 71, 73 and a threshold Vthn of the n-MOS transistors 84, 86 satisfy Vthp=Vthn=0.5 V, the input signal Vin=0V to 3 V, the higher supply voltage Vgg=25 V, and the lower supply voltage Vee=−15V. In this case, initially, when Vin=1.5 V, the electric potential of the node N4 is calculated as Vgg−3×Vthp=23.5V, and the electric potential of the node N5 is calculated as Vee+3×Vthn=−13.5 V.

When Vin=0 V (L level), N4=22 V (L level) and N5=−15 V (L level) are satisfied due to the coupling effect. Consequently, the p-MOS transistor M7 is turned ON, the n-MOS transistor M8 is turned OFF, and the electric potential of the node N1 becomes Vgg=25 V.

Further, when Vin=3 V (H level), N4=25 V (H level) and N5=−12 V (H level) are satisfied due to the coupling effect. Consequently, the p-MOS transistor M7 is turned OFF, the n-MOS transistor M8 is turned ON, and the electric potential of the node N1 becomes Vee=−15 V. Thus, the electric potential of the node N1 swings fully between Vgg and Vee.

The semiconductor device of this embodiment enables driving of the output circuit 61 by the input signal Vin of a logic unit (Vdd≈3 V, Vss=0 V) without depending on the higher supply voltage Vgg (Vgg≈25 V) and the lower supply voltage Vee (Vee≈−15 V).

Since voltage level conversion, e.g., a conversion from Vdd/Vss to Vα/Vee, is not required, there is an advantage that a full swing waveform of Vgg/Vee can be obtained as an output signal Vout.

As described above, the voltage output circuit 90 of the semiconductor device of this embodiment includes the multiple output circuits 92, and includes the third and fourth constant voltage generation circuits 93, 94. Each of the output circuits 92 includes the drive circuit 91 having the first and second constant voltage generation circuits 95, 96. The third and fourth constant voltage generation circuits 93, 94 are connected in common to the drive circuits 91.

Therefore, the chip size of the semiconductor device constituting the voltage output circuit 90 can be reduced. Further, the output circuit 61 can be driven by the input signal Vin of logic potentials without depending on the higher supply voltage Vgg and the lower supply voltage Vee. As a result, the full swing waveform of Vgg/Vee can be acquired as the output signal Vout.

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device, comprising an input node, a drive circuit, a first p-channel insulated-gate field-effect transistor, an output circuit and an output node, wherein
the output circuit includes first and second n-channel insulated-gate field-effect transistors connected to each other in series, a drain of the first n-channel insulated-gate field-effect transistor is connected to a first line, a source of the first n-channel insulated-gate field-effect transistor is connected to the output node, a back gate of the first n-channel insulated-gate field-effect transistor is connected to the source, a drain of the second n-channel insulated-gate field-effect transistor is connected to the output node, a source of the second n-channel insulated-gate field-effect transistor is connected to a second line, a back gate of the second n-channel insulated-gate field-effect transistor is connected to the source of the second n-channel insulated-gate field-effect transistor, a source of the first p-channel insulated-gate field-effect transistor is connected to the first line, a drain of the first p-channel insulated-gate field-effect transistor is connected to the output node, and a back gate of the first p-channel insulated-gate field-effect transistor is connected to the source of the first p-channel insulated-gate field-effect transistor, and wherein
the drive circuit generates first and second control signals to turn on and off the first and second n-channel insulated-gate field-effect transistors in a complementary manner, and generates a third control signal to control the first p-channel insulated-gate field-effect transistor, in response to an input signal provided to the input node, the first, the second and the third control signals being respectively outputted to gates of the first and the second n-channel insulated-gate field-effect transistors and to a gate of the first p-channel insulated-gate field-effect transistor.

2. The semiconductor device according to claim 1, wherein the second control signal is the input signal.

3. The semiconductor device according to claim 1, wherein
an n-type source region, an n-type drain region, and a p-type high impurity concentration region of the first n-channel insulated-gate field-effect transistor are formed in a p-type well region which is formed in an n-type well region arranged in a p-type semiconductor substrate,
a gate insulating film of the first n-channel insulated-gate field-effect transistor is formed on a semiconductor region positioned between the n-type source region and the n-type drain region,
a gate electrode is formed on the gate insulating film, and
the p-type high impurity concentration region of the first n-channel insulated-gate field-effect transistor is electrically connected to the n-type source region of the first n-channel insulated-gate field-effect transistor.

4. The semiconductor device according to claim 1, wherein
the drive circuit includes a first CMOS inverter connected between the first and second lines, and an output of the first CMOS inverter is inputted to the gate of the first n-channel insulated-gate field-effect transistor as the first control signal.

5. The semiconductor device according to claim 4, further comprising a second CMOS inverter receiving an output of the first CMOS inverter, an output of the first CMOS inverter being inputted to the gate of the first n-channel insulated-gate field-effect transistor as the fist control signal, an output of the second CMOS inverter being inputted to the gate of the first p-channel insulated-gate field-effect transistor as the third control signal, an input signal provided to the first CMOS inverter being inputted to the gate of the second n-channel insulated-gate field-effect transistor as the second control signal.

6. The semiconductor device according to claim 1, wherein
the drive circuit includes a bootstrap circuit having third, fourth, and fifth n-channel insulated-gate field-effect transistors, and a capacitor, a drain of the third n-channel insulated-gate field-effect transistor being connected to the first line, a source of the third n-channel insulated-gate field-effect transistor being connected to a drain of the fourth n-channel insulated-gate field-effect transistor, a gate of the third n-channel insulated-gate field-effect transistor being connected to the drain of the fourth n-channel insulated-gate field-effect transistor via the capacitor, a source of the fourth n-channel insulated-gate field-effect transistor being connected to the second line, the input signal being inputted to a gate of the fourth n-channel insulated-gate field-effect transistor, a drain and a gate of the fifth n-channel insulated-gate field-effect transistor being connected to the first line, a source of the fifth n-channel insulated-gate field-effect transistor being connected to the gate of the third n-channel insulated-gate field-effect transistor.

7. The semiconductor device according to claim 1, wherein
the drive circuit includes a constant voltage generation circuit, a second p-channel insulated-gate field-effect transistor, a sixth n-channel insulated-gate field-effect transistor, a capacitor, and a CMOS inverter, one end of the constant voltage generation circuit being connected to the first line, a different end of the constant voltage generation circuit being connected to one end of the capacitor, a source of the second p-channel insulated-gate field-effect transistor being connected to the first line, a drain of the second p-channel insulated-gate field-effect transistor being connected to a drain of the sixth n-channel insulated-gate field-effect transistor, to an input terminal of the CMOS inverter, and to the gate of the first n-channel insulated-gate field-effect transistor, a gate of the second p-channel insulated-gate field-effect transistor being connected to the one end of the capacitor, a source of the sixth n-channel insulated-gate field-effect transistor is connected to the second line, a gate of the sixth n-channel insulated-gate field-effect transistor being connected to the input node and to a different end of the capacitor, the CMOS inverter is connected between the first line and the second line, an output terminal of the CMOS inverter is connected to the gate of the second n-channel insulated-gate field-effect transistor.

8. The semiconductor device according to claim 7, wherein
the constant voltage generation circuit includes a plurality of n-channel or p-channel insulated-gate field-effect transistors connected to each other in series, and a gate and a drain of each of the n-channel or p-channel insulated-gate field-effect transistors are connected to each other.

9. The semiconductor device according to claim 8, wherein
a withstand voltage between each two of the electrodes of at least one of the n-channel or p-channel insulated-gate field-effect transistors is lower than a withstand voltage between each two of the electrodes of any one of the second n-channel insulated-gate field-effect transistor and the first p-channel insulated-gate field-effect transistor.

10. A semiconductor device, comprising an input node, a plurality of voltage output circuits each including an output circuit and a drive circuit including a first constant voltage generation circuit, a second constant voltage generation circuit, and an output node, wherein
the output circuit includes first and second n-channel insulated-gate field-effect transistors connected to each other in series, and a first p-channel insulated-gate field-effect transistor, a drain of the first n-channel insulated-gate field-effect transistor being connected to a first line, a source of the first n-channel insulated-gate field-effect transistor being connected to the output node, a back gate of the first n-channel insulated-gate field-effect transistor being connected to the source, a drain of the second n-channel insulated-gate field-effect transistor being connected to the output node, a source of the second n-channel insulated-gate field-effect transistor being connected to a second line, a back gate of the second n-channel insulated-gate field-effect transistor being connected to the source of the second n-channel insulated-gate field-effect transistor, a source of the first p-channel insulated-gate field-effect transistor being connected to the first line, a drain of the first p-channel insulated-gate field-effect transistor being connected to the output node, a back gate of the first p-channel insulated-gate field-effect transistor being connected to the source of the first p-channel insulated-gate field-effect transistor, and wherein
the drive circuit further includes a second p-channel insulated-gate field-effect transistor, a third n-channel insulated-gate field-effect transistor, a capacitor, and a CMOS inverter, one end of the first constant voltage generation circuit is connected to one end of the second constant voltage generation circuit, another end of the first constant voltage generation circuit is connected to one end of the capacitor, and the CMOS inverter is connected between the first and second lines, a source of the second p-channel insulated-gate field-effect transistor being connected to the first line, a drain of the second p-channel insulated-gate field-effect transistor is connected to a drain of the third n-channel insulated-gate field-effect transistor, to an input terminal of the CMOS inverter, and to a gate of the first n-channel insulated-gate field-effect transistor, a gate of the second p-channel insulated-gate field-effect transistor being connected to the one end of the capacitor, a source of the third n-channel insulated-gate field-effect transistor being connected to the second line, a gate of the third n-channel insulated-gate field-effect transistor being connected to a different end of the capacitor, the input node being connected to any one of the gate of the second p-channel insulated-gate field-effect transistor and the gate of the third n-channel insulated-gate field-effect transistor, an output terminal of the CMOS inverter being connected to a gate of the second n-channel insulated-gate field-effect transistor and a gate of the first p-channel insulated-gate field-effect transistor, another end of the second constant voltage generation circuit being connected to the first line.

11. The semiconductor device according to claim 10, wherein the input node is connected to the gate of the third n-channel insulated-gate field-effect transistor.

12. The semiconductor device according to claim 10, wherein the input node is connected to the gate of the second p-channel insulated-gate field-effect transistor.

13. The semiconductor device according to claim 10, wherein
the second constant voltage generation circuit includes a plurality of n-channel or p-channel insulated-gate field-effect transistors connected to each other in series, and a gate and a drain of each of the n-channel or p-channel insulated-gate field-effect transistors are connected to each other.

14. The semiconductor device according to claim 10, wherein
an n-type source region, an n-type drain region, and a p-type high impurity concentration region of the first n-channel insulated-gate field-effect transistor are formed in a p-type well region which is arranged in an n-type well region formed in a p-type semiconductor substrate,
a gate insulating film of the first n-channel insulated-gate field-effect transistor is formed on a semiconductor region formed between the n-type source region and the n-type drain region,
a gate electrode is formed on the gate insulating film, and
the p-type high impurity concentration region of the first n-channel insulated-gate field-effect transistor is electrically connected to the n-type source region of the first n-channel insulated-gate field-effect transistor.

15. The semiconductor device according to claim 10, wherein
the first constant voltage generation circuit includes an n-channel insulated-gate field-effect transistor, and a drain and a gate of the n-channel insulated-gate field-effect transistor are connected to each other.

16. A semiconductor device, comprising an input node, a plurality of voltage output circuits, third and fourth constant voltage generation circuits and an output node, each of the voltage output circuits including an output circuit and a drive circuit having first and second constant voltage generation circuits, wherein
the output circuit includes a first p-channel insulated-gate field-effect transistor and first and second n-channel insulated-gate field-effect transistors connected to each other in series, a drain of the first n-channel insulated-gate field-effect transistor being connected to a first line, a source of the first n-channel insulated-gate field-effect transistor being connected to the output node, a back gate of the first n-channel insulated-gate field-effect transistor being connected to the source, a drain of the second n-channel insulated-gate field-effect transistor being connected to the output node, a source of the second n-channel insulated-gate field-effect transistor being connected to a second line, a back gate of the second n-channel insulated-gate field-effect transistor being connected to the source of the second n-channel insulated-gate field-effect transistor, a source of the first p-channel insulated-gate field-effect transistor being connected to the first line, a drain of the first p-channel insulated-gate field-effect transistor being connected to the output node, a back gate of the first p-channel insulated-gate field-effect transistor being connected to the source of the first p-channel insulated-gate field-effect transistor, wherein
the drive circuit further includes a second p-channel insulated-gate field-effect transistor, a third n-channel insulated-gate field-effect transistor, first and second capacitors, and a CMOS inverter,
one end of the first constant voltage generation circuit is connected to one end of the third constant voltage generation circuit,
another end of the first constant voltage generation circuit is connected to one end of the first capacitor,
the CMOS inverter is connected between the first and second lines,
a source of the second p-channel insulated-gate field-effect transistor is connected to the first line, a drain of the second p-channel insulated-gate field-effect transistor being connected to a drain of the third n-channel insulated-gate field-effect transistor, to an input terminal of the CMOS inverter, and to a gate of the first n-channel insulated-gate field-effect transistor, a gate of the second p-channel insulated-gate field-effect transistor being connected to the one end of the first capacitor, and wherein
a source of the third n-channel insulated-gate field-effect transistor is connected to the second line, a gate of the third n-channel insulated-gate field-effect transistor being connected to one end of the second capacitor and to one end of the second constant voltage generation circuit,
one end of the fourth constant voltage generation circuit is connected to another end of the second constant voltage generation circuit,
the input node is connected to other ends of the respective first and second capacitors,
an output terminal of the CMOS inverter is connected to a gate of the second n-channel insulated-gate field-effect transistor and a gate of the first p-channel insulated-gate field-effect transistor,
another end of the third constant voltage generation circuit is connected to the first line, and
another end of the fourth constant voltage generation circuit is connected to the second line.

17. The semiconductor device according to claim 16, wherein
the third constant voltage generation circuit includes a plurality of p-channel insulated-gate field-effect transistors connected to each other in series, a gate and a drain of each of the p-channel insulated-gate field-effect transistors being connected to each other, and wherein
the fourth constant voltage generation circuit includes a plurality of n-channel insulated-gate field-effect transistors connected to each other in series, a gate and a drain of each of the n-channel insulated-gate field-effect transistors being connected to each other.

18. The semiconductor device according to claim 16, wherein
an n-type source region, an n-type drain region, and a p-type high impurity concentration region of the first n-channel insulated-gate field-effect transistor are formed in a p-type well region which is arranged in an n-type well region formed in a p-type semiconductor substrate,
a gate insulating film of the first n-channel insulated-gate field-effect transistor is formed on a semiconductor region formed between the n-type source region and the n-type drain region,
a gate electrode is formed on the gate insulating film, and wherein
the p-type high impurity concentration region of the first n-channel insulated-gate field-effect transistor is electrically connected to the n-type source region of the first n-channel insulated-gate field-effect transistor.

19. The semiconductor device according to claim 16, wherein
the first constant voltage generation circuit includes a p-channel insulated-gate field-effect transistor, a drain and a gate of the p-channel insulated-gate field-effect transistor being connected to each other, and wherein
the second constant voltage generation circuit includes an n-channel insulated-gate field-effect transistor, a drain and a gate of the n-channel insulated-gate field-effect transistor being connected to each other.
